(19) United States
(12) Patent Application Publication
(10) Pub. No.: US 2024/0347509 A1
(43) Pub. Date: Oct. 17, 2024

(54) SEMICONDUCTOR PACKAGE STRIP AND METHOD FOR FORMING A SEMICONDUCTOR DEVICE

(71) Applicant: JCET STATS ChipPAC Korea Limited, Incheon (KR)

(72) Inventors: HyeonChul LEE, Seoul (KR); KyoungHee PARK, Seoul (KR); KyungHwan KIM, Seoul (KR); SeungHyun LEE, Incheon (KR)

(21) Appl. No.: 18/636,301

(22) Filed: Apr. 16, 2024

(30) Foreign Application Priority Data
Apr. 17, 2023 (CN) 202310408186.3

(51) Int. Cl. H01L 25/065; H01L 23/00; H01L 23/31; H01L 23/60; H01L 25/00

(52) U.S. Cl. CPC H01L 25/0655; H01L 23/3121; H01L 23/60; H01L 24/94; H01L 25/50; H01L 24/16; H01L 2224/16225; H01L 2224/94; H01L 2924/1815

(57) ABSTRACT

A semiconductor package strip is provided. The semiconductor package strip includes: a substrate; a first set of electronic components and a first external connector attached on the substrate; a second set of electronic components and a second external connector attached on the substrate; wherein the first set of electronic components are adjacent to the second set of electronic components, and the first and second external connectors are disposed at two sides of the first and second sets of electronic components, respectively; an encapsulant layer formed on the substrate, wherein the encapsulant covers the first and second sets of electronic components but exposes the first and second external connectors; and a saw street in between the first and second sets of electronic components that allows for singulation of the semiconductor package strip at the saw street.

### TECHNICAL FIELD

The present application generally relates to semiconductor technology, and more particularly, to a semiconductor package strip and a method for forming a semiconductor device.

### BACKGROUND OF THE INVENTION

The semiconductor industry is constantly faced with complex integration challenges. The production process of a semiconductor package is complicated and of high cost. Especially for the 5G antenna-in-package product with specific semiconductor package design such as a selective molding with connector area, there exist various process risks and the production efficiency is limited.

Therefore, a need exists for a method for forming a semiconductor device with higher production efficiency.

### SUMMARY OF THE INVENTION

An objective of the present application is to provide a semiconductor package strip that allows for higher production efficiency.

According to an aspect of the present application, a semiconductor package strip is provided. The semiconductor package strip may comprise: a substrate; a first set of electronic components and a first external connector attached on the substrate; a second set of electronic components and a second external connector attached on the substrate; wherein the first set of electronic components are adjacent to the second set of electronic components, and the first and second external connectors are disposed at two sides of the first and second sets of electronic components, respectively; an encapsulant layer formed on the substrate, wherein the encapsulant covers the first and second sets of electronic components but exposes the first and second external connectors; and a saw street in between the first and second sets of electronic components that allows for singulation of the semiconductor package strip at the saw street.

According to another aspect of the present application, a method for forming a semiconductor device is provided. The method may comprise: providing a substrate; attaching a first set of electronic components and a second set of electronic components onto the substrate; attaching a first external connector onto a first side of the first and second sets of electronic components; attaching a second external connector onto a second side of the first and second sets of electronic components, wherein the second side is opposite to the first side; forming an encapsulant layer on the substrate to cover the first and second sets of electronic components but expose the first and second external connectors; and singulating the substrate and the encapsulant layer at a saw street in between the first and second sets of electronic components to separate the first set of electronic components and the first external connector from the second set of electronic components and the second external connector.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A and 1B illustrate a top view and a cross-sectional view of a conventional semiconductor package strip, respectively.

FIG. 2A illustrates a top view of a semiconductor package strip according to an embodiment of the present application.

FIG. 2B illustrates a column of the semiconductor package strip shown in FIG. 2A.

FIG. 2C illustrates a cross-sectional view of a semiconductor package strip according to an embodiment of the present application.

FIGS. 3A to 3E illustrate cross-sectional views of steps of a method for forming a semiconductor package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” ors “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another clement(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other clement, or intervening elements may be present.

In semiconductor packages such as 5G antenna-in-packages, each package may include encapsulated electronic components as well as external connector(s) that are not encapsulated. These encapsulated electronic components may be further shielded by a conductive layer to avoid the impact of external electromagnetic interference (EMI). The semiconductor packages may take the form of a strip where a plurality of sets of electronic components are mounted in parallel, which may be easier to be encapsulated at a same time and then be singulated into individual pieces. Due to package design and production capability, in production, the semiconductor package strip of such package design may include some large dummy area for singulation purpose, i.e., saw streets. Therefore, the production of semiconductor packages from such semiconductor package strips is limited if the dummy areas occupy a significant portion of the package strips.

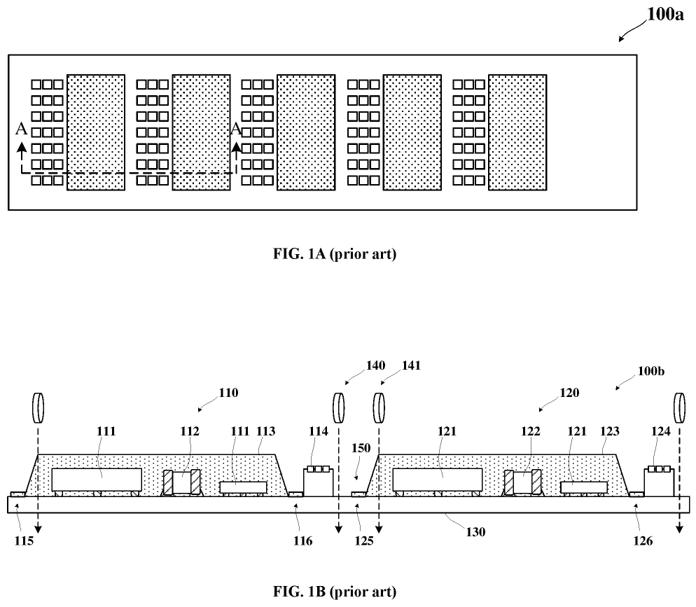

FIG. 1A illustrates a top view of a conventional semiconductor strip design. As shown in FIG. 1A, a semiconductor package strip 100a accommodates 5 columns of semiconductor packages to be singulated from the strip 100a. Each column further includes 7 semiconductor packages molded with a same encapsulant layer. Therefore, the semiconductor package strip 100a may allow for production of 5*7=35 semiconductor packages. Specifically, each two columns of semiconductor packages may have a cross-sectional view along line AA as shown in FIG. 1B.

FIG. 1B illustrates a cross-sectional view of a row 100b of two columns of the conventional semiconductor package strip 100a including two semiconductor packages 110 and 120 on a common substrate 130. The semiconductor package 110 may include multiple electronic components 111, 112 and an encapsulant layer 113 encapsulating the electronic components 111 and 112. The semiconductor package 110 may also include an external connector 114 not encapsulated. Similar as the semiconductor package 110, the semiconductor package 120 may include another set of electronic components such as electronic components 121, 122, which are encapsulated by another encapsulant layer 123, and an external connector 124 which is not encapsulated. The semiconductor packages 110 and 120 may be spaced from each other to allow for subsequent singulation. Specifically, the closest components of the two semiconductor packages 110 and 120, i.e., the external connector 114 of the semiconductor package 110 and the molded electronic component 121 of the semiconductor package 120 are spaced from each other such that the packages 110 and 120 can be safely singulated from each other at saw streets 140 and 141 with sufficient clearances. A dummy area 150 is reserved for the saw streets 140 and 141 between the semiconductor packages 110 and 120 for assuring that the singulation does not harm the electronic components of the semiconductor packages 110 and 120. The dummy area 150 also leaves some space for mold flash, i.e., excess molding materials that forms on the surface of the substrate 130 during the molding process, which will be elaborated below. Optionally, the saw street 141 which is closer to the semiconductor package 120 may ensure that a lateral surface of the encapsulant layer 123 of the semiconductor package 120 is perpendicular to the substrate 130 after singulation. In total, as shown in FIG. 1B, four saw streets are needed for singulating the two semiconductor packages from each other and further from the semiconductor package strip in a row direction.

It can be seen that, in the conventional design, since dummy areas between adjacent semiconductor packages are needed, thus the space utilization of the package strip is relatively limited.

Still referring to FIG. 1B, the electronic components of multiple semiconductor packages on the substrate is encapsulated by respective encapsulant layers which can be formed by molding such as injection molding or compression molding. For example, in the step of forming the encapsulant layer 113 over the electronic components for the semiconductor package 110, mold flash may be formed at the foot of the encapsulant layer 113, such as at positions 115 and 116. Similarly, when forming the encapsulant layer 123, mold flash may be formed at positions 125 and 126. That is to say, for the two semiconductor packages formed with two separate encapsulant layers 113 and 123, there are four positions susceptible to mold flash in the cross-sectional view, which need some space reserved for the potential occurrence of the mold flash. Furthermore, the mold flash may be harmful for subsequent processing steps and product quality, for example, preventing the deposition of a shielding material on the surface of the substrate.

In order to address at least some of the drawbacks of the conventional semiconductor package strip, the present application proposes a novel semiconductor package strip design with higher space efficiency and reduced process risk.

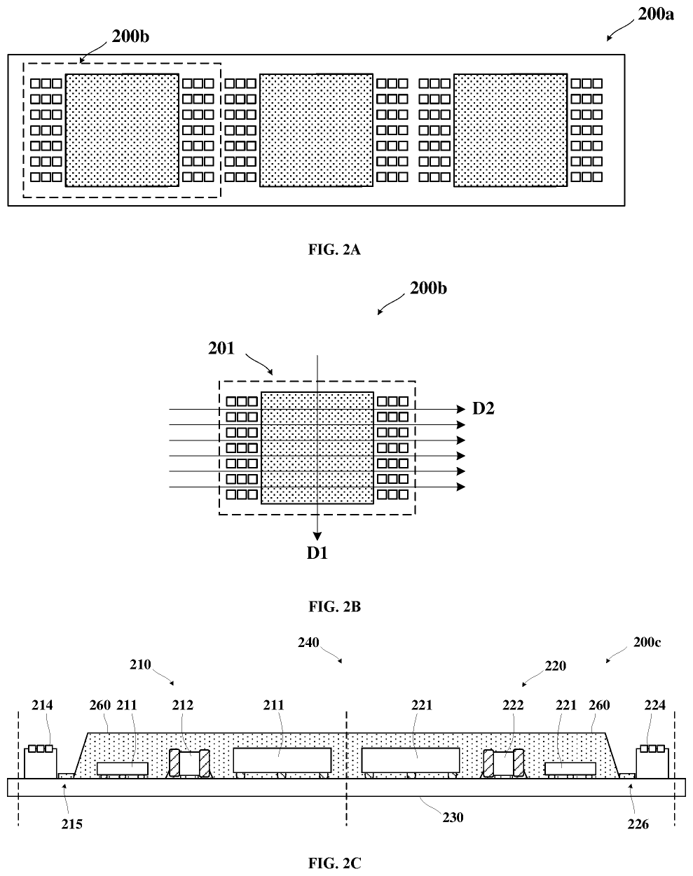

FIGS. 2A to 2C illustrate a semiconductor package strip according to an embodiment of the present application.

As shown in FIG. 2A, the semiconductor package strip 200a has a same area as the semiconductor package strip 100a shown in FIG. 1A. The semiconductor package strip 200a accommodates 3 columns of semiconductor packages which may be further singulated from the semiconductor package strip 200a. The semiconductor packages of each column 200b are molded with a same encapsulant layer. Specifically, each column 200b of semiconductor packages includes two sub-columns of semiconductor packages, as shown in FIG. 2B. Each sub-column includes 7 semiconductor packages, which is the same as the semiconductor package strip 100a shown in FIG. 1A. Therefore, the semiconductor package strip 200a may allow for a production of 3*2*7=42 semiconductor packages.

Comparing the embodiment shown in FIG. 2A to the conventional package strip design shown in FIG. 1A, the dummy area to the left of the semiconductor package strips 200a and 100b may be of the same width. Yet, the semiconductor package strip 100a of the conventional design cannot allow for a further column of semiconductor packages as in the semiconductor package strip 200a shown in FIG. 2A, because in the conventional design, more dummy areas are needed between each two adjacent columns of semiconductor packages. As can be seen, the layout of the semiconductor package strip 200a shown in FIG. 2A is more tight, thereby allows for production of more semiconductor packages in the same area.

Referring to FIG. 2B, each column 200b shown in FIG. 2A is further illustrated. The column 200b includes two sub-columns 201, and each sub-column includes 7 semiconductor packages in 7 rows, respectively. In production, singulation may be performed to the column 200b first along line D1 and then along line D2, or in a reversed order. When multiple columns are on the same substrate such as illustrated in FIG. 2A, the multiple columns may be singulated from each other at the same time or at different times from the singulation along line D1.

FIG. 2C illustrates a cross-sectional view of one row 200c of the column 200b of the semiconductor package strip shown in FIG. 2B. As shown in FIG. 2C, the partial semiconductor package strip 200c includes two semiconductor packages 210 and 220 on the common substrate 230 that are arranged in a row. The semiconductor package 210 may include a first set of electronic components 211, 212 and an external connector 214 attached on the substrate 230. Similar as the semiconductor package 210, the semiconductor package 220 may include similar components such as a second set of electronic components 221, 222 and an external connector 224. Specifically, the first set of electronic components 211, 212 arc adjacent to the second set of electronic components 221, 222, and the first and second external connectors 214 and 224 are disposed at two sides of the first and second sets of electronic components 211, 212, 221 and 222, respectively. An encapsulant layer 260 is formed on the substrate 230 covering the first set of electronic components 211, 212 and the second set of electronic components 221, 222. The external connectors 214 and 224 are exposed from the encapsulant layer 260. A saw street 240 is reserved in between the first and second sets of electronic components 211, 212 and 221, 222, which allows for singulation of the semiconductor packages 210 and 220 from each other at the saw street 240.

Still referring to FIG. 2C, in some embodiments, the first set of electronic components 211, 212 and the first external connector 214 are identical to and symmetrically disposed on the substrate 230 to the second set of electronic components 221, 222 and the second external connector 224 with respect to the saw street 240. It can be understood that, in some alternative embodiments, the first set of electronic components 211, 212 may be different from the second set of electronic components 221, 222. Also, the positions of the first set of electronic components and the second set of electronic components may be not identical or symmetric to each other with respect to the saw street 240. For example, the first set of electronic components may be closer to the saw street 240 than the second set of electronic components, as long as the clearance for singulation can be ensured. In some embodiments, the first and second external connectors 214 and 224 are board-to-board connectors. It can be understood that, the first and second external connectors 214 and 224 may be other types of external connectors, such as flexible printed circuit (FPC) connectors, for electrically connecting the semiconductor packages 210 and 220 to other external components or devices, respectively. In some embodiments, each set of the first and second sets of electronic components includes at least one semiconductor die. In some embodiments, the electronic components 211 and 221 are semiconductor dice that may or may not have the same functions. In some embodiments, the electronic components 212 and 222 may be active or passive electronic components that may or may not have the same functions. Active electronic components, including bipolar and field effect transistors, control the flow of electrical current. Passive electronic components, including resistors, capacitors, and inductors, create a relationship between voltage and current necessary to perform a variety of electrical functions. The passive and active electronic components are electrically connected to form circuits, which enable the semiconductor package to perform high-speed calculations and other useful functions. In some embodiments, the substrate 230 may be a printed circuit board (PCB). In some embodiments, the substrate 230 may be a PCB and may include a redistribution structure (RDS) having one or more dielectric layers and one or more conductive layers between and through the dielectric layers (not shown). The conductive layers may define pads, traces, and plugs through which electrical signals or voltages can be distributed horizontally and vertically across the RDS. In some embodiments, the RDS may include a plurality of conductive patterns formed on both or either of the top and bottom surfaces of the substrate 230. It can be understood that the substrate may be other components for desired electronic connection of electronic components thereon.

It can be seen that, the dummy area 150 shown in FIG. 1B are not desired for the partial package strip 200c shown in FIG. 2C. Therefore, a total length of a row of semiconductor packages 210 and 220 on the partial semiconductor package strip 200b may be smaller than the total length of a row of the two columns of two semiconductor packages 110 and 120 shown in FIG. 1B. That is to say, a tighter semiconductor package strip design can be realized. It can be understood that, the distance between the two closest components of the two semiconductor packages 210 and 220 in the encapsulant layer 260 may be adjusted as needed. Also, as shown in the embodiment shown in FIG. 2C, 3 saw streets for the two semiconductor packages are needed in a cross-sectional direction, which is less than 4 saw streets shown in the conventional design shown in FIG. 1B. Therefore, the semiconductor package strip design according to the embodiments of the present application can have a reduced number of saw streets, as well as a reduced number of singulation operations, if the same number of packages are singulated from the strips. In addition, the tighter layout of the semiconductor package strip is advantageous, since the semiconductor package strips of the same area may allow for production of more semiconductor packages.

Still referring to FIG. 2C, since the two semiconductor packages are formed with the common encapsulant layer 260, there are only two positions 215 and 226 susceptible to mold flash in the cross-sectional view, less than the four positions susceptible to mold flash as described with reference to the conventional strip design shown in FIG. 1B. As such, the semiconductor package strip design according to the embodiments of the present application allows for reduced positions susceptible to possible mold flash risk. It should be noted that, the mold flash at positions 215 and 216 are for illustration only, and may not actually exist.

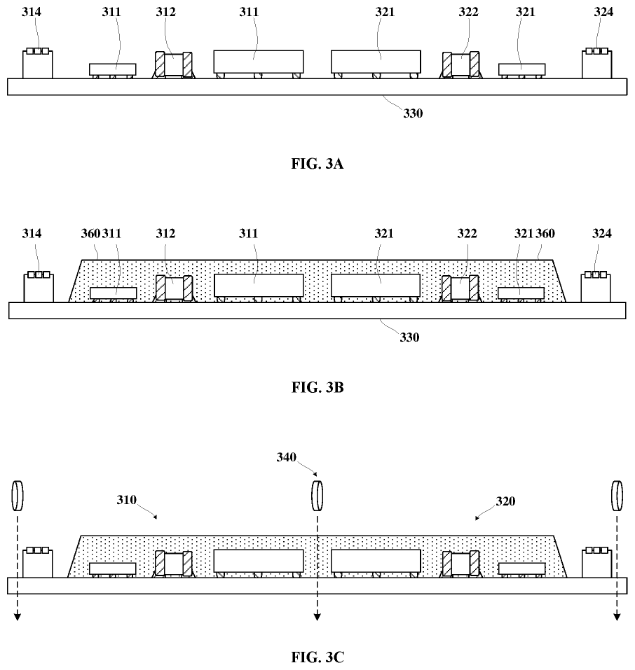

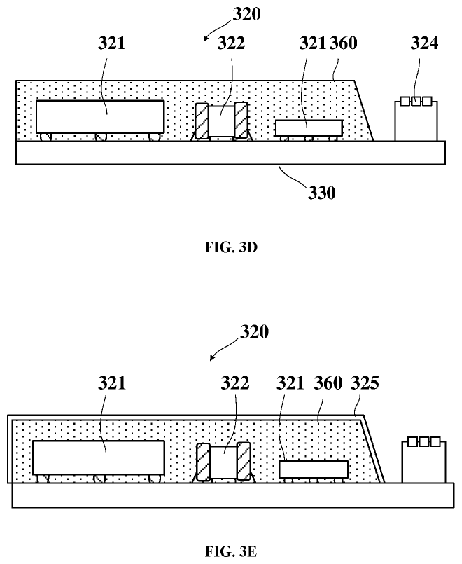

FIGS. 3A to 3E illustrate cross-sectional views of various steps of a method for forming a semiconductor package according to an embodiment of the present application. The method may be performed to the semiconductor package strip as shown in FIG. 2A, for example.

As shown in FIG. 3A, a substrate 330 is provided, a first set of electronic components 311, 312 and a second set of electronic components 321, 322 are attached onto the substrate 330. Also, a first external connector 314 is attached onto one side of the first and second sets of electronic components while a second external connector 324 is attached onto the opposite side of the first and second sets of electronic components.

As shown in FIG. 3B, a common encapsulant layers 360 is formed on the substrate 330. The encapsulant layer 330 covers the first set of electronic components 311, 312, the second set of electronic components 321, 322, but exposes the first and second external connectors 314 and 324 from the substrate 330. In some embodiments, the encapsulant layer 360 may be formed by depositing an encapsulant or molding compound over the electronic components 311, 312 and 321, 322, on the substrate 330 using injection molding, compressive molding, transfer molding, liquid encapsulant molding, vacuum lamination, spin coating, or another suitable processes. The encapsulant can be a polymer composite material, such as epoxy resin, epoxy acrylate, or any suitable polymer with or without filler. The encapsulant may be non-conductive, provides structural support, and environmentally protects the electronic devices from external elements and contaminants. The encapsulated first set of electronic components 311, 312, the first external connector 314 and the portion of the substrate 330 where they are attached form a first semiconductor package; while the encapsulated second set of electronic components 321, 322, the second external connectors 324 and the portion of the substrate 330 where they are attached form a second semiconductor package.

Afterwards, referring to FIG. 3C, the first semiconductor package 310 and the second semiconductor package 320 are separated and singulated from each other at a saw street 340. Preferably, the saw street 340 may be arranged such that it is in the middle of the closest electronic components of the semiconductor packages 310 and 320. Preferably, the distance between the saw street and the closest electronic components of the semiconductor packages 310 and 320 may be 200 um to 20 mm, for example.

In some embodiments, the saw street 340 may be determined based on a reference on the substrate. For example, the external connectors which are not encapsulated by the encapsulant layer may be used as the reference, and the saw street 340 may be of a predetermined distance from the reference. In some other embodiments, a saw street mark such as a cross sign or a line sign may be formed on the top surface of the encapsulant layer for easy observation during the singulation operation.

Referring to FIG. 3D, the singulated semiconductor package 320 is shown. The singulated semiconductor package 320 may include the electronic components 321, 322, the external connector 324, a portion of the encapsulant layer 360 encapsulating the electronic components 321, 322, and a portion of the substrate 330.

Referring to FIG. 3E, optionally, the semiconductor package 320 is formed with a shielding layer 325 on top of the encapsulant layer 360, to shield the second set of electronic components 321, 322 from external EMI. In some embodiments, the shielding layer may be formed by a selective deposition of a shielding material over the encapsulant layer 360. The shielding layer 325 may be formed by spray coating, plating, sputtering, or any other suitable metal deposition process. In some embodiments, the shielding layer 325 may be an EMI shielding layer of copper, aluminum, iron, or any other suitable material. As such, a semiconductor device can be formed from the semiconductor package 320.

The discussion herein included numerous illustrative figures that showed various portions of a semiconductor package strip and method for making a semiconductor device. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package strip, comprising:
a substrate;
a first set of electronic components and a first external connector attached on the substrate;
a second set of electronic components and a second external connector attached on the substrate; wherein the first set of electronic components are adjacent to the second set of electronic components, and the first and second external connectors are disposed at two sides of the first and second sets of electronic components, respectively;
an encapsulant layer formed on the substrate, wherein the encapsulant layer covers the first and second sets of electronic components but exposes the first and second external connectors; and
a saw street in between the first and second sets of electronic components that allows for singulation of the semiconductor package strip at the saw street.

2. The semiconductor package strip of claim 1, wherein the first set of electronic components and the first external connector are identical to and symmetrically disposed on the substrate to the second set of electronic components and the second external connector with respect to the saw street.

3. The semiconductor package strip of claim 1, wherein the first and second external connectors are board-to-board connectors.

4. The semiconductor package strip of claim 1, wherein each of the first and second sets of electronic components comprises at least one semiconductor die.

5. A method for forming a semiconductor device, comprising:
providing a substrate;
attaching a first set of electronic components and a second set of electronic components onto the substrate;
attaching a first external connector onto a first side of the first and second sets of electronic components;
attaching a second external connector onto a second side of the first and second sets of electronic components, wherein the second side is opposite to the first side;
forming an encapsulant layer on the substrate to cover the first and second sets of electronic components but expose the first and second external connectors; and
singulating the substrate and the encapsulant layer at a saw street in between the first and second sets of electronic components to separate the first set of electronic components and the first external connector from the second set of electronic components and the second external connector.

6. The method of claim 5, further comprising:
forming a shielding layer on each of the encapsulant layers covering the first set of electronic components and the second set of electronic components.

7. The method of claim 5, wherein the first set of electronic components and the first external connector are identical to and symmetrically disposed on the substrate to the second set of electronic components and the second external connector with respect to the saw street.

8. The method of claim 5, wherein the first and second external connectors are board-to-board connectors.

9. The method of claim 5, wherein each of the first and second sets of electronic components comprises at least one semiconductor die.

10. A semiconductor device, formed using a method comprising the following steps:
providing a substrate;
attaching a first set of electronic components and a second set of electronic components onto the substrate;
attaching a first external connector onto a first side of the first and second sets of electronic components;
attaching a second external connector onto a second side of the first and second sets of electronic components, wherein the second side is opposite to the first side;
forming an encapsulant layer on the substrate to cover the first and second sets of electronic components but expose the first and second external connectors; and
singulating the substrate and the encapsulant layer at a saw street in between the first and second sets of electronic components to separate the first set of electronic components and the first external connector from the second set of electronic components and the second external connector.
